(19) United States
(12) Patent Application Publication
(10) Pub. No.: US 2010/0213545 A1
(43) Pub. Date: Aug. 26, 2010

(54) MOS TRANSISTOR WITH A P-FIELD IMPLANT OVERLYING EACH END OF A GATE THEREOF

(75) Inventors: Ching Tee Elizabeth Kho, Sarawak (MY); Mee Guoh Michael Tiong, Sarawak (MY); Kia Yaw Kee, Sarawak (MY); Wen Jun Li, Shanghai (CN); Wenyi Li, Shanxi Province (CN); Michael May, Sarawak (MY); Chean Chian Alain Liew, Singapore (SG)

Correspondence Address: LAWRENCE Y.D. HO & ASSOCIATES PTE LTD, 30 BIDEFORD ROAD, #02-02, THONGSIA BUILDING, SINGAPORE, 229922, SG

(73) Assignee: X-FAB SEMICONDUCTOR FOUNDRIES AG, Erfurt (DE)

(21) Appl. No.: 12/601,821

(22) PCT Filed: May 15, 2008
(86) PCT No.: PCT/MY2008/000044

§ 371 Date: May 11, 2010

(30) Foreign Application Priority Data
May 29, 2007 (MY) PI 20070840

(51) Int. Cl. H01L 29/78; H01L 21/336

(52) U.S. Cl. 257/339; 438/289; 257/E21.417; 257/E29.256

(57) ABSTRACT

The present invention provides a method for fabricating a MOS transistor (100) with suppression of edge transistor effect. In one embodiment of an NMOS, an elongate implant limb (110, HOa, 114) extends from each of two sidewalls (14a, 14b) of a p-type well (14) to partially wrap around each respective longitudinal end of the gate (20) and to overlay a portion thereof. In another embodiment, the elongate implant limb (110, 110a) extends into the drain/source drift region (32, 42). The NMOS transistor (100) thus fabricated allows the NMOS transistor to operate at relatively high voltages with reduced drain leakage current but with no additional masks or process time in the process integration.

### FIELD OF INVENTION

The present invention relates to the fabrication of MOS transistors. In particular, the invention relates to a method for fabricating high-voltage NMOS transistors with improved characteristics.

### BACKGROUND

High voltage power integrated circuits (IC) devices are growing in demand, such as in flat panel display drivers, power regulators, motor controllers, and so on. These power IC are often integrated with low voltage circuitry on a single chip, for example, using the standard metal-oxide-semiconductor (MOS) technology.

A typical MOS transistor 10 consists of a gate 20, a drain 30 and a source 40. The drain 30 and the source 40 can be n-type or p-type material. FIG. 1 shows the basic structure of the typical high-voltage N-type MOS transistor 10. As the name implies, prior art MOS gate 20 consists of a metal layer built on an oxide layer 22. A recent MOS gate 20 typically consists of a doped polycrystalline silicon (polysilicon) layer 24 built on the oxide layer 22. In modern MOS gate, the polysilicon layer 24 is replaced by high dielectric materials, such as oxides or oxy-nitrides of zirconium, hafnium, aluminium, silicon and so on. As shown in FIG. 1, the high-voltage (HV) NMOS transistor 10 is built in a deep retrograde p-type well 14 formed on a p-type substrate 12. Each HV NMOS transistor 10 is isolated from an adjacent device by a pair of isolators 60. The drain 30 and source 40 regions are typically referred to as “active” regions A of the NMOS transistor 10. Further, as shown in FIG. 1, a body terminal 50 is electrically connected to the p-well 14. In operation, the body 50 and the source 40 are electrically connected to the ground terminal.

The HV NMOS transistor 10 shown in FIG. 1 is of a lateral double-diffused or LD MOS structure, in which the source/drain and gate channel regions are isolated by shallow trench isolators (STI) 62. The drain 30 and source 40 active regions are implanted with n-type material and laterally diffused or drifted into the gate region; the drift implants corresponding to the drain and source regions are labeled drift implants 32, 42. The drain 30, source 40 and gate 20 are then connected by vias for further connection through respective terminals 35, 45 and 28.

The MOS fabrication techniques rely heavily on masking and etching of materials on a semiconductor wafer. Inherently, the walls of a well or recess created by etching are not entirely vertical. FIG. 2A shows a plan view of an NMOS transistor structure showing two active drift implant regions 32, 42 and a gate 20 therebetween. FIG. 2B shows a sectional view of the transistor 10 along a longitudinal axis BB of the gate 20. As can be seen from FIG. 2B, the gate oxide 22 at the two longitudinal ends of the gate 20 is thinner; this may be due to high mechanical stress at the ends of the gate 20. As a result, the channel concentration at the ends of the gate 20 is lower and the NMOS transistor 10 behaves like an ideal central transistor 10a connected in parallel to an edge transistor 10b. During operation, the edge transistor 10b is turned on at a lower gate voltage than that of the central transistor 10a, that is, the edge transistor 10b has a lower threshold voltage Vt. The different threshold voltages Vt of the edge and main transistor are reflected as humps H1, H2 in the drain current (I_{D})-gate voltage (V_{G}) characteristic in FIG. 2C. The undesirable edge or parasitic transistor effect creates this so-called double-hump phenomenon. The double hump phenomenon is more significant when the transistor body 50 is negatively biased. As can be seen from FIG. 2C, when the transistor body is more negatively biased, the transfer characteristic is shifted further to the right, thus making the double hump phenomenon more pronounced.

In operation, the double-hump NMOS characteristic results in a small drain leakage current. With power ICs using high voltage NMOS transistors integrated with low-voltage MOS devices, drain leakage current poses a problem, especially for portable electronic equipment running on batteries, which have finite battery power.

The double-hump phenomenon also appears to be caused by other IC fabrication techniques. For example, Cho, et al. in “The Effect of Corner Transistors in STI-isolated SOI MOSFETs”, Seoul National University Journal, vol. 28, 2005, discusses the effect of parasitic transistor created at the corners of the gate TEOS sidewalls. A similar subject of discussion is also made by Haneder, et al., “Optimization of Ultra High Density MOS Arrays in 3D”, Proceeding of the 27^{th} European, Solid-State Device Research Conference, 22-24 Sep. 1997, pp 268-271.

It can thus be seen that there exists a need for a method for fabricating MOS devices with improved transistor characteristic and lower drain current leakage. In the corollary, the threshold voltage Vt of the edge transistor needs to be increased to suppress the double hump phenomenon.

### SUMMARY

The following presents a simplified summary to provide a basic understanding of the present invention. This summary is not an extensive overview of the invention, and is not intended to identify key features of the invention. Rather, it is to present some of the inventive concepts of this invention in a simplified form as a prelude to the detailed description that is to follow.

The present invention provides a method for fabricating a transistor with suppressed edge transistor effect. The method comprises: forming an elongate limb to extend from each of two sidewalls of an implanted well in which the transistor is fabricated such that said elongate limb partially wraps around a respective end of a gate and overlies a portion thereof so that the transistor does not exhibit a double-hump transfer characteristic at relatively high gate voltages. Thus, a transistor fabricated according to the present invention has reduced drain leakage current.

In one embodiment of the elongate limb, each limb extends into the transistor's active drift implant regions by a dimension Y. In one embodiment, the dimension Y ranges from about 0 to about 1 μm. In another embodiment, the width T of the limb ranges from about 0.3 μm to about 5 μm. In yet another embodiment, the limb is formed by doping with a concentration that ranges from about 1×10¹² to about 4×10¹⁵ atoms/cm².

In one embodiment of the transistor, the transistor is an NMOS and the well is doped with a p-type material. The concentration of the p-type doping in the elongate limbs may be the same or different from that in the p-well.

In another embodiment of the transistor, the elongate limbs are parallel to and overlay a longitudinal axis of the gate. In another embodiment, the elongate limbs are offset from the longitudinal axis of the gate towards the drain side. In yet another embodiment, the elongate limbs are joined up with each other. In yet a further embodiment, each elongate limb further comprises a vertical limb portion extending from the respective sidewall of the p-well.

### BRIEF DESCRIPTION OF THE DRAWINGS

This invention will be described by way of non-limiting embodiments of the present invention, with reference to the accompanying drawings, in which:

FIG. 1 illustrates a typical section of a high-voltage n-channel or NMOS transistor fabricated with drift implants;

FIG. 2A is a plan view of a typical NMOS transistor structure with drift implants;

FIG. 2B is a sectional view BB along a longitudinal gate dimension of the NMOS transistor structure shown in FIG. 2A; and

FIG. 2C is a typical double-hump transfer characteristic of the NMOS transistor shown in FIG. 2A;

FIG. 3A illustrates a cross-sectional view of a high voltage NMOS transistor structure according to an embodiment of the present invention;

FIG. 3B illustrates a plan view of the high voltage NMOS transistor structure shown in FIG. 3A;

FIG. 3C illustrates a HV NMOS transistor structure according to another embodiment of the present invention;

FIG. 4 illustrates a transfer characteristic of the HV NMOS transistor of the present invention;

FIG. 5A illustrates a drain current-channel width characteristic of an NMOS transistor without p-field implant, whilst FIG. 5B illustrates a drain current-channel width characteristic of an NMOS transistor of the present invention;

FIG. 6 is a flow chart illustrating the process steps in fabricating the high voltage NMOS transistor according to the present invention; and

FIG. 7A-7G illustrate cross-sections of the high voltage NMOS transistor formed with a fabrication process according to another embodiment of the present invention.

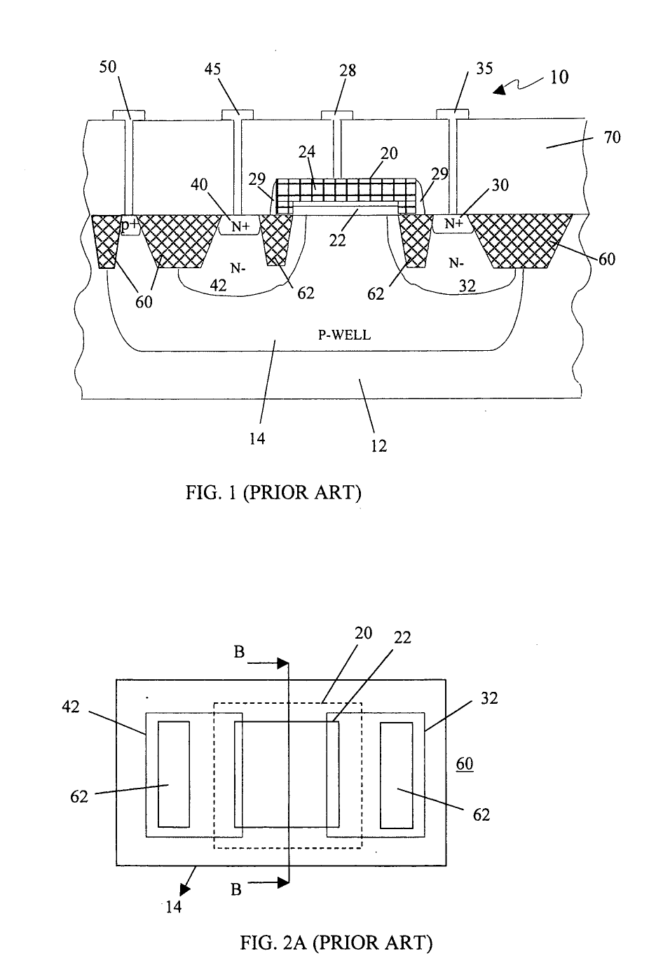

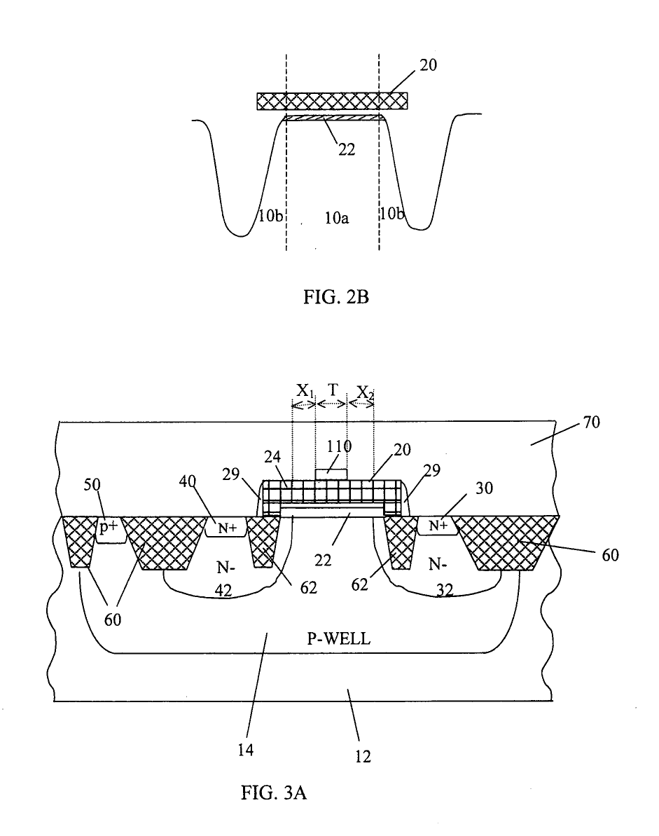

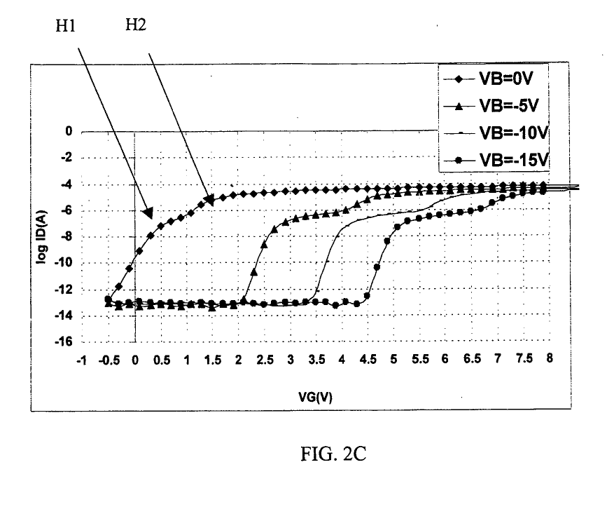

### DETAILED DESCRIPTION

One or more specific and alternative embodiments of the present invention will now be described with reference to the attached drawings. It shall be apparent to one skilled in the art, however that this invention may be practised without such specific details. Some of the details may not be described at length so as not to obscure the invention. For ease of reference, common reference numerals or series of numerals will be used throughout the figures when referring to the same or similar features common to the figures.

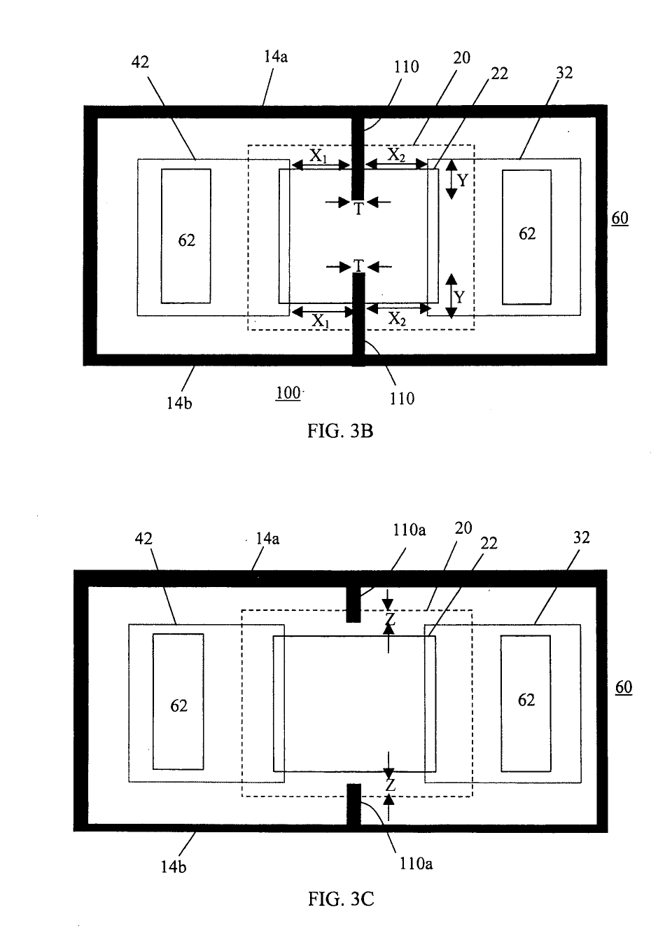

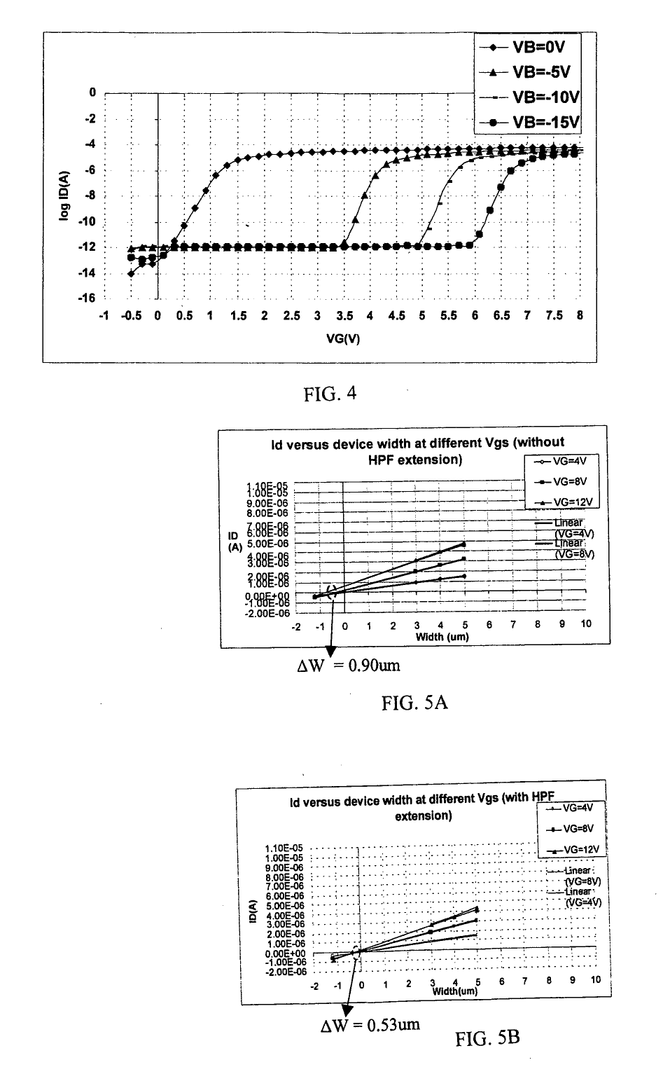

FIG. 3A illustrates an embodiment of a high-voltage (HV) NMOS transistor structure 100 according to the present invention. As shown in a longitudinal section of the gate as in FIG. 3A, the upper part of the deep p-well 14 wall is formed a p-field implanted elongate limb 110 to partially wrap around and overlay each of the two ends of the gate 20. Each elongate limb 110 extends from an upper part of the sidewall 14a of the deep p-well 14 with the elongate limb's longitudinal axis parallel to the longitudinal axis of the gate 20. In a similar manner, the opposite end of the gate 20 has another elongate limb 110 partially extending from the opposite side of the sidewall 14b of the deep p-well 14 and overlying this opposite end of the gate 20. In one embodiment, the width T of the elongate limb 110 ranges from about 0.3 μm to about 5 μm. FIG. 4 shows the transfer characteristic of the HV NMOS transistor 100 fabricated according to the present invention. As can be seen from FIG. 4, there is no double-hump phenomenon in the transfer characteristic of the HV NMOS transistor 100 of the present invention.

FIG. 3B shows a plan view of the high-voltage NMOS transistor 100 shown in FIG. 3A. As can be seen from FIG. 3B, each elongate limb 110 overlaps the edge of the gate 20 in the longitudinal axis so that the elongate limb 110 is spaced from the source and drain drift implants 32, 42 by respective dimensions X1 and X2; in one embodiment of the elongate limb 110, dimensions X1 and X2 are approximately equal; in another embodiment, X1 and X2 are unequal. As can also be seen, each elongate limb 110 ends at the boundary of the active transistor regions or drift regions 32, 42 or extends into the boundary by dimension Y. In one embodiment, dimension X ranges from 0 to about 5 μm. In another embodiment, dimension Y ranges from 0 to about 1 μm. Dimensions X and Y may be varied depending on the concentration of the p-type doping material. In one embodiment, the concentration of the p-field implantation ranges from about 1×10¹² to about 4×10¹⁴ atoms/cm². In one embodiment, the elongate limb 110 does not extend to the center of the gate 20 so that the elongate limb 110 would not interfere with the gate via structure 28 that extends up from the gate 20, for example, for external connection.

The inventors have found that forming each p-field implanted limb 110 to partially wrap over and overlay each end of the gate 20 advantageously modifies the electric field around each longitudinal end of the gate 20. As a result, the p-field limbs 110 suppress the undesirable effect of the edge transistors and minimize the leakage current that causes the double-hump character.

The threshold voltage Vt can be analysed by the effective gate channel width W. The threshold voltage Vt of the edge or corner transistor corresponding to a wider channel width (W+ΔW) is given by the following equation:

$$\begin{matrix}Id = ( W + Δ W ) \cdot μ \cdot {C}_{OX} \cdot ( {V}_{GS} - Vt ) \cdot V / {L}_{eff} \\ = A \cdot ( W + Δ W )\end{matrix}$$

wherein A is a process constant;

ΔW is the increase in channel width, W;

μ is the surface mobility of transistor;

Cₒₓ is the capacitance per unit area of gate oxide; and

L_{eff} is the effective channel length.

From the above equation, it is noted that the drain current Id is a linear function of the channel width W. By measuring the drain currents Id and plotting them against different channel widths W, the negative x-axis intercept would give a measure of the increase ΔW in channel width. One way of reducing the double hump phenomenon is to reduce the channel width W and increase the channel concentration. FIG. 5A shows the Id-W characteristic for a transistor without p-field implanted limb 110, whilst FIG. 5B shows the Id-W characteristic for a transistor with p-field implanted limbs 110.

FIG. 3C shows a high voltage NMOS transistor structure according to another embodiment of the present invention. As shown in FIG. 3C, each elongate limb 110a partially wraps around each longitudinal end of the gate 20 and extends to the boundary of the gate active region or drift regions 32, 42, that is, by a dimension Z. In one embodiment, dimension Z ranges from 0 μm to about 10 μm.

In an embodiment where the sidewalls 14a, 14b of the deep p-well 14 may not extend to a horizontal plane at the same level as the top of the gate 20, each elongate limb 110, 110a may include a vertical limb portion 114 extending from the sidewalls 14a, 14b. In one embodiment, the cross-section of the elongate limb 110, 11a and/or vertical limb portion 114 is/are quadrilateral or square; in another embodiment, the cross-section of the elongate limb 110, 11a and/or vertical limb portion 114 is/are formed in other shapes. In another embodiment, the cross-sectional area of the elongate limb 110, 110a and/or vertical limb portion 114 is/are non-uniform; the cross-sectional area may be variable, for example, is tapering. In yet another embodiment, the elongate limb 110, 110a and/or the vertical limb portion 114 is/are formed with two or more components.

As the source 30 and the body 50 are typically grounded in an NMOS transistor 100, the electric field in the active drain region is high. To modify the high electric filed in the gate 20 at the drain side, the elongate limb 110, 110a and/or the vertical limb portion 114 is offset from the longitudinal axis of the gate 20 towards the drain 30 side in a further embodiment of the present invention, such as for an asymmetric MOS device having only a drain drift region 32. In another embodiment of this NMOS transistor 100, the two elongate opposing limbs 110, 110a are joined up to form a single elongate limb overlying the entire longitudinal length of the gate 20 at the drain 30 side without interfering with the gate via structure 28.

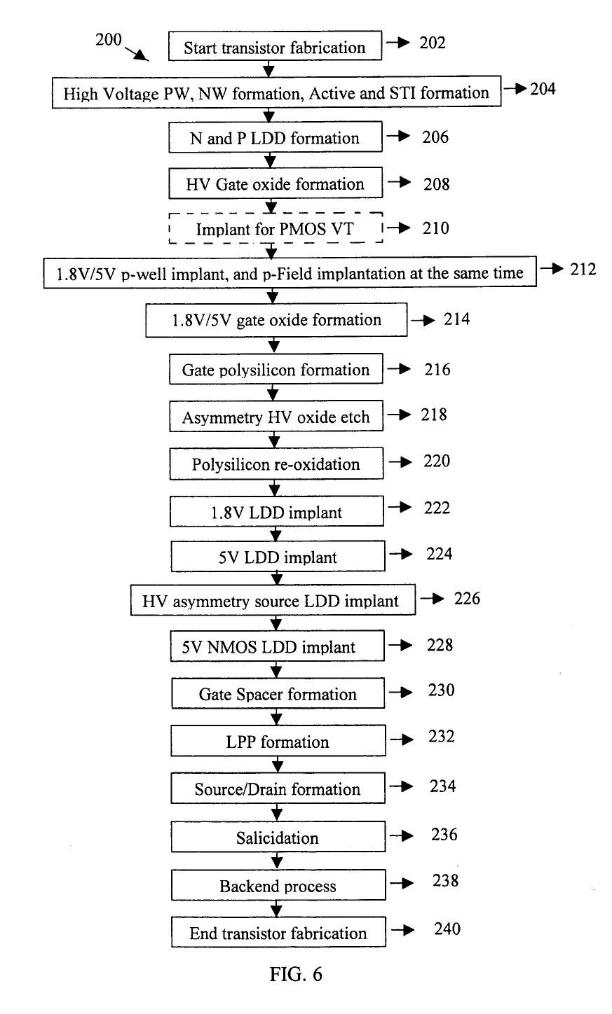

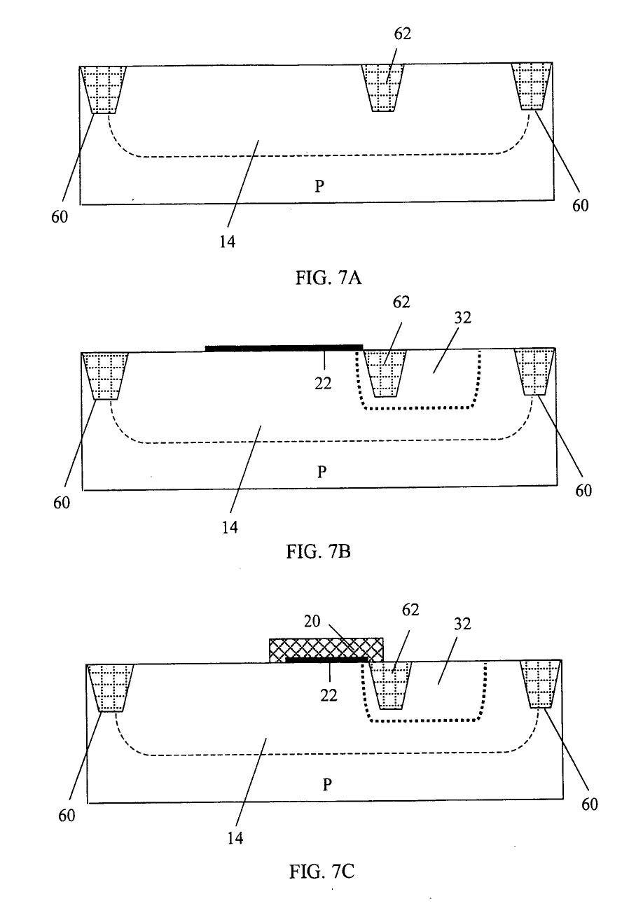

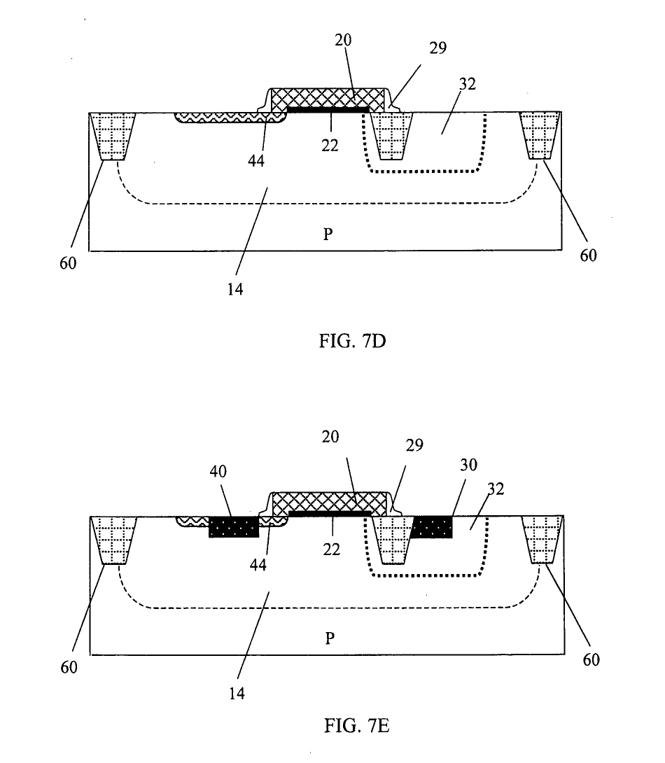

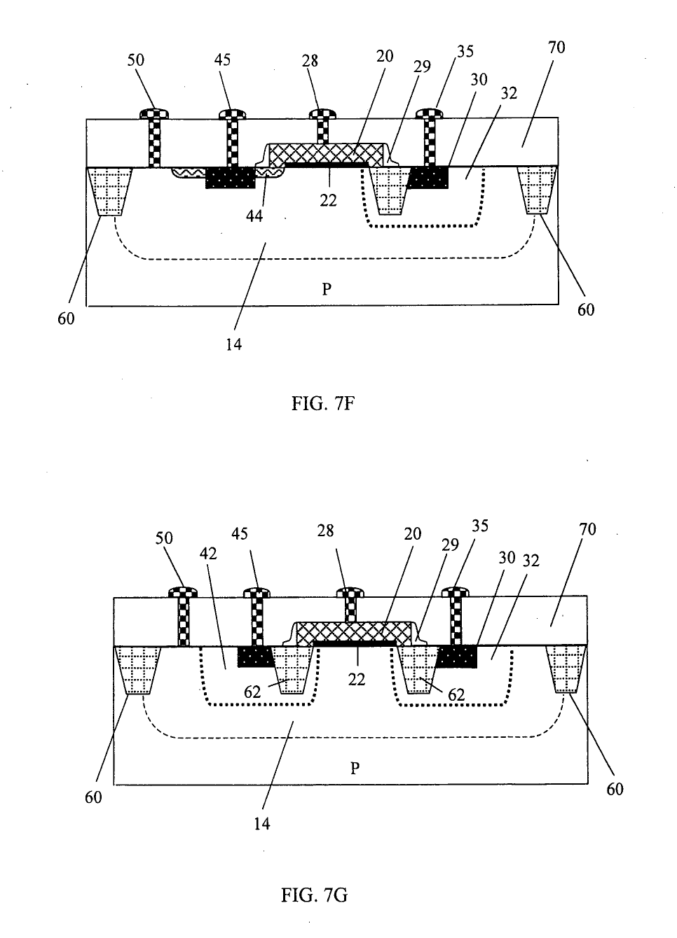

FIG. 6 shows a flow chart illustrating the principal process 200 in the fabrication of a high voltage (HV) NMOS transistor 100 according to the present invention. FIG. 7A-7F illustrate cross-sections of asymmetric HV NMOS transistors 100 formed with the process 200; FIG. 7G illustrates a cross-section of a symmetric HV NMOS transistor formed with the process 200.

As shown in FIG. 6, the fabrication process 200 starts with step 202. In step 202, a p-type substrate 12 is prepared and the fabrication process 200 is initiated. In step 204, the p-well 14 is implanted and heat-treated so that the p-well 14 envelop moves towards the baseline of the substrate. The active area and field area A of the high-voltage NMOS transistor 100 are then defined by isolations 60, such as, shallow trench isolators (STI) or local oxidation of silicon (LOCOS). This partial fabrication of the HV NMOS transistor 100 is shown in FIG. 7A. In step 206, the drain 30 and source 40 regions are implanted with n-type dopants. The n-type dopants are then diffused by employing the Reduced Surface Field (RESURF) technique. The NMOS transistor 100 formed with the RESURF technique has the transistor breakdown region located in the bulk under the gate oxide 22 rather than at the surface, thus allowing higher transistor breakdown voltage at the drain 30. In the next process, i.e. step 208, the partially processed substrate 12 undergoes furnace annealing to form the high-voltage gate oxide 22; partial fabrication of the HV NMOS transistor 100 is now shown in FIG. 7B.

In the next process at step 212, low voltage (LV) (for example, 1.8 and 5 V) implants (such as, anti-punch through, corner transistor Vt adjustment, and so on) and wells are formed for low voltage transistor devices that are complementary to the HV NMOS transistors 100. At the same time, the p-field implantation process for forming the p-field implanted limb 110, 110a is formed with the same masks and implant conditions with such LV p-well implants. The p-field implantation process is common to both the HV and LV devices and there is no additional cost incurred in respect to additional masks and process time. Following this, LV gate oxides are then formed by a thermal oxidation process, in step 214, on the LV devices. Polysilicon 20 is then deposited, patterned and etched, in step 216, to form the gate electrodes for both the HV and LV devices. Asymmetry HV oxide etch is then performed in step 218, followed by a polysilicon re-oxidation process in step 220; partial fabrication of the HV NMOS transistor 100 is now shown in FIG. 7C.

As shown in FIG. 6, the drain and source implantations for HV and LV devices are then performed before forming gate spacers 29 in step 230. For example, in step 222, 1.8V LDD source and drain extension implants are performed for LV devices, followed by 5V LDD source and drain implants for both LV and HV devices in step 224 and HV asymmetry source LDD implant in step 226; these LDD implants are then diffused in a furnace before 5V NMOS LDD implant for both LV and HV devices is carried out in step 228. FIG. 7D illustrates partial fabrication of a HV NMOS transistor 100 after a HV asymmetry drain LDD implant 32, source implant 44 and gate spacer 29 formation.

As shown in FIG. 6, after forming the gate spacers 29 in step 230, drain 30 and source 40 regions for both LV and HV devices are implanted in step 234. The implanted drain/source regions are then self-aligned with respect to the gate spacers 29 in a salicidation process in step 236; the partially formed asymmetric HV NMOS transistor 100 is shown in FIG. 7E. The formed HV NMOS transistor 100 and any complementary LV devices thus formed are then filled with a dielectric 70, such as silicon dioxide. The dielectric 70 is then patterned and etched to form vias to the source, drain and gate regions; these vias are filled with a conductor, such as, metals to form electrical connections 45, 35, 28 to the source, drain and gate. FIG. 7F shows a HV asymmetric NMOS transistor 100 fabricated according to the fabrication process 200; FIG. 7G shows a HV symmetric NMOS transistor 100 fabricated according to process 200.

As shown in FIG. 6, the HV NMOS transistor fabrication is then completed with some backend processes, which are collectively grouped under step 238, before the HV NMOS fabrication process 200 ends in step 240.

In another embodiment of the HV NMOS fabrication process 200, an addition low doped polysilicon (LPP) implantation in step 232 is performed between the gate spacer 29 forming step 230 and the drain/source forming step 234. This LPP implantation provides an additional implant layer to give the polysilicon 20 high resistance.

In another embodiment of the HV NMOS fabrication process 200, the HV asymmetry source LDD implant is integrated with the 5V LDD implant, that is, process steps 226 is integrated into step 224.

While specific embodiments have been described and illustrated, it is understood that many changes, modifications, variations and combinations thereof could be made to the present invention without departing from the scope of the invention. For example, the elongate limb 110 may be formed with a higher concentration of p-type material than the sidewalls of the deep p-well such that the dimensions X, Y and Z can be varied, yet allowing the elongate limbs 110 to advantageously suppress the expression of the edge transistors at the longitudinal ends of the gate 20. Although a high-voltage NMOS structure 100 has been used in the description, a person skilled in the art would appreciate that the principle of this invention can also be applied to suppress leakage currents in PMOS transistors. For example, in fabricating a PMOS transistor, an additional process step 210 is carried after process step 208. In process step 210, the PMOS channel is implanted to adjust the PMOS threshold voltage towards the desired specification. The 5V PMOS LDD implant may then be carried out in process step 224. Whilst specific diffusion techniques have not been described, a skilled person would appreciate that different diffusion techniques, such as lateral double diffusion (LDD) or drift/extended drain (DD) can be incorporated into the present invention.

1. A method of fabricating a transistor with reduced leakage current, said method comprising:
forming an elongate limb to extend from each of two sidewalls of an implanted well in which the transistor is fabricated such that said elongate limb partially wraps around a respective end of a gate and overlies a portion thereof so that the transistor does not exhibit a double-hump transfer characteristic at relatively high gate voltages.

2. A method according to claim 1, wherein each elongate limb extends into the transistor's active or drift implant regions by a dimension Y.

3. A method according to claim 2, wherein the dimension Y ranges from about 0 to about 1 μm.

4. A method according to claim 1, wherein each elongate limb extends from the gate to the transistor's active or drift implant region by a dimension Z.

5. A method according to claim 4, wherein the dimension Z ranges from about 0 to about 10 μm.

6. A method according to claim 1, wherein a width T of the elongate limb ranges from about 0.3 to about 5 μm.

7. A method according to claim 1, wherein the elongate limb is formed by doping with a concentration that ranges from about 1×10¹² to about 4×10¹⁵ atoms/cm².

8. A method according to claim 1, wherein said transistor is an NMOS and the well is doped with a p-type material.

9. A method according to claim 8, wherein a concentration of the p-type doping in the elongate limbs is substantially the same as that in the implanted well.

10. A method according to claim 8, wherein a concentration of the p-type doping in the elongate limbs is different from that in the implanted well.

11. A method according to claim 1, wherein a longitudinal axis of the elongate limbs is parallel to a longitudinal axis of the gate.

12. A method according to claim 11, wherein the longitudinal axis of the elongate limbs overlies the longitudinal axis of the gate such that the elongate limbs overlay a central portion of the gate.

13. A method according to claim 11, wherein the longitudinal axis of the elongate limbs is offset from the longitudinal axis of the gate towards the drain side.

14. A method according to claim 13, wherein the elongate limbs join up with each other.

15. A method according to claim 1, further comprising forming a vertical limb portion extending from each of the two sidewalls of the implanted well.

16. A method of suppressing the edge transistor effect of a semiconductor transistor device according to claim 1, wherein the transistor is operable at relatively high voltages.

17. A MOSFET device with reduced leakage current being fabricated according to claim 1, wherein the transistor is operable at relatively high voltages.
